(19) United States
(12) Patent Application Publication
(10) Pub. No.: US 2026/0244529 A1
(43) Pub. Date: Aug. 20, 2026

(54) MEMORY DEVICE INCLUDING ERROR CORRECTION CODE ENGINE AND MEMORY SYSTEM INCLUDING THE SAME

(71) Applicant: SK hynix Inc., Gyeonggi-do (KR)

(72) Inventors: Seon Woo HWANG, Gyeonggi-do (KR); Seong Jin KIM, Gyeonggi-do (KR); Jung Hwan JI, Gyeonggi-do (KR)

(21) Appl. No.: 19/271,785

(22) Filed: Jul. 17, 2025

(30) Foreign Application Priority Data
Feb. 18, 2025 (KR) 10-2025-0020607

(51) Int. Cl. G06F 11/10

(52) U.S. Cl. CPC G06F 11/1044; G06F 11/1048

(57) ABSTRACT

A memory system includes first and second memory devices configured to selectively share a first data pad based on a channel mode, each of the first and second memory devices including: a data latch circuit configured to variably delay a read signal according to a channel mode signal corresponding to the channel mode to generate a first delayed read signal, latch read data output from a memory cell region according to the read signal, and output the latched read data as delayed data according to the first delayed read signal; and an error correction code (ECC) engine configured to correct an error in the delayed data based on a read error correction code read from the memory cell region to generate error-corrected data.

### CROSS-REFERENCE TO RELATED APPLICATIONS

The present application claims the benefit of Korean Patent Application No. 10-2025-0020607, filed on Feb. 18, 2025, which is incorporated herein by reference in its entirety.

### BACKGROUND

### 1. Field

Various embodiments of the present disclosure relate to a semiconductor design technology, and more particularly, to a memory device with an error correction code (ECC) engine for supporting various channel modes.

### 2. Description of the Related Art

The semiconductor industry is seeing rapid advancement and changes. For example, in semiconductor devices, such as memory devices, the time required to satisfy various operation-related specifications is decreasing due to the increase in operating speed, and accordingly, the bit error rate is increasing. Therefore, these memory devices are known to be equipped with an error correction code (ECC) engine to correct error bits.

Furthermore, to provide flexibility in data transmission, a memory device may support various channel modes. Depending on the configured channel mode, the memory device may provide independent command/address pads (or pins) and data pads (or pins) for each channel, or may be configured such that a predetermined number of channels share the command/address pads and data pads.

In a memory device equipped with an ECC engine, various methods are under study to minimize the skew of signals transmitted through different signal paths in each channel mode.

### SUMMARY

Embodiments of the present disclosure are directed to a memory system capable of minimizing the skew among signals input to and output from a plurality of memory devices in various channel modes.

In accordance with an embodiment of the present disclosure, a memory system includes first and second memory devices configured to selectively share a first data pad based on a channel mode, each of the first and second memory devices including: a data latch circuit configured to variably delay a read signal according to a channel mode signal corresponding to the channel mode to generate a first delayed read signal, latch read data output from a memory cell region according to the read signal, and output the latched read data as delayed data according to the first delayed read signal; and an error correction code (ECC) engine configured to correct an error in the delayed data based on a read error correction code read from the memory cell region to generate error-corrected data.

In accordance with an embodiment of the present disclosure, a memory device includes a memory cell region configured to output read data and a read error correction code according to a read signal; a delay adjustment circuit configured to delay the read signal by one of a first channel delay and a second channel delay according to a channel mode signal to generate a first delayed read signal; a timing compensation circuit configured to latch the read data according to the read signal, and output the latched read data as delayed data according to the first delayed read signal; and an ECC engine configured to correct an error in the delayed data based on the read error correction code to generate error-corrected data.

In accordance with an embodiment of the present disclosure, a memory device includes a delay adjustment circuit configured to delay a write signal by one of a first channel delay and a second channel delay according to a channel mode signal to generate a first delayed write signal; a timing compensation circuit configured to latch write data based on the write signal, and output the latched write data as delayed data according to the first delayed write signal; and an ECC engine configured to generate a preliminary error correction code based on the write data.

According to embodiments of the present disclosure, the memory system can improve a timing margin for an ECC operation thereby enhancing the reliability of the ECC operation, by minimizing the skew among the signals delivered to ECC engines included in a plurality of memory devices in various channel modes.

In addition, according to embodiments of the present disclosure, the memory device can provide performance suitable for various application environments while guaranteeing high-speed operation, by optimizing timing differences caused by physical/structural variations, while also providing flexibility in design.

These and other features and advantages of the embodiments of the present disclosure will become apparent to those skilled in the art from the following detailed description in conjunction with the following drawings.

### BRIEF DESCRIPTION OF THE DRAWINGS

FIGS. 1A and 1B are block diagrams illustrating a configuration of a memory system in a 2-channel (2-CH) mode and a 4-channel (4-CH) mode in accordance with an embodiment of the present disclosure.

FIGS. 2A and 2B are block diagrams for describing a write operation and a read operation in a 2-CH mode and a 4-CH mode in accordance with an embodiment of the present disclosure.

FIG. 3 is a block diagram illustrating a memory device in accordance with an embodiment of the present disclosure.

FIG. 4 is a detailed configuration diagram illustrating a data processing circuit of FIG. 3 in accordance with an embodiment of the present disclosure.

FIGS. 5A and 5B are detailed configuration diagrams illustrating a first delay adjustment circuit of FIG. 4, in accordance with an embodiment of the present disclosure.

FIGS. 6A and 6B are detailed configuration diagrams of a second delay adjustment circuit of FIG. 4, in accordance with an embodiment of the present disclosure.

FIG. 7 is a detailed circuit diagram illustrating a timing control circuit of FIG. 4 in accordance with an embodiment of the present disclosure.

FIG. 8 is a detailed circuit diagram illustrating a timing compensation circuit of FIG. 4 in accordance with an embodiment of the present disclosure.

FIGS. 9A and 9B are timing diagrams for describing an operation of memory devices within a memory chip in accordance with an embodiment of the present disclosure.

### DETAILED DESCRIPTION

Various embodiments of the present disclosure will be described below in more detail with reference to the accompanying drawings. The embodiments of the present disclosure may, however, be in different forms and should not be construed as limited to the embodiments set forth herein. Rather, these embodiments are provided so that this disclosure will be thorough and complete, and will fully convey the scope of the present disclosure to those skilled in the art. Throughout this disclosure, like reference numerals refer to like parts throughout the various figures and embodiments of the present disclosure.

It will be understood that when an element is referred to as being “coupled” or “connected” to another element, it may mean that the two are directly coupled or the two are electrically connected to each other with another circuit intervening therebetween. It will be further understood that the terms “comprise”, “include”, “have”, etc. when used in this specification, specify the presence of stated features, numbers, steps, operations, elements, components, and/or combinations of them but do not preclude the presence or addition of one or more other features, numbers, steps, operations, elements, components, and/or combinations thereof. In the present disclosure, the singular forms are intended to include the plural forms as well, unless the context clearly indicates otherwise.

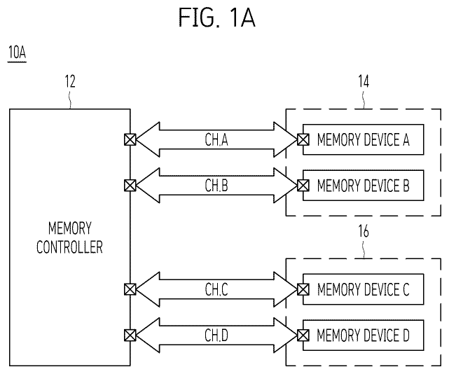

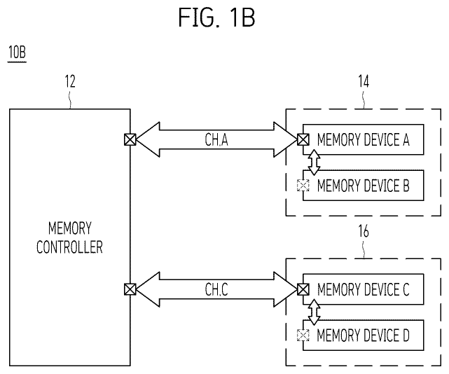

FIGS. 1A and 1B are block diagrams illustrating a configuration of a memory system 10A and 10B in a 2-channel (2-CH) mode and a 4-channel (4-CH) mode in accordance with an embodiment of the present disclosure.

Referring to FIGS. 1A and 1B, the memory system 10A and the memory system 10B may include a memory controller 12 and memory chips 14 and 16. Each of the memory chips 14 and 16 may include a plurality of memory devices. For example, the memory chip 14 may include memory devices A and B, and the memory chip 16 may include memory devices C and D.

As shown in FIG. 1A, when the memory system 10A is configured in the four channel (4-CH) mode, the memory devices A, B, C, and D may form channels CH.A, CH.B, CH.C, and CH.D, respectively, which independently communicate with the memory controller 12 through physically separate command/address/data pads (or pins). That is, through the respective channels CH.A, CH.B, CH.C, and CH.D, the memory controller 12 may independently provide command/address signals to each of the memory devices A, B, C, and D, and independently transmit and receive data to and from the memory devices A, B, C, and D.

In contrast, as shown in FIG. 1B, when the memory system 10B is configured in the two channel (2-CH) mode, the memory chips 14 and 16 may form channels CH.A and CH.C, respectively, which independently communicate with the memory controller 12 through physically separate command/address/data pads (or pins). The memory devices A and B of the memory chip 14 may share the command/address/data pads arranged in the memory device A to form the channel CH.A, and the memory devices C and D of the memory chip 16 may share the command/address/data pads arranged in the memory device C to form the channel CH.C.

That is, through the command/address/data pads arranged in the memory device A, the memory controller 12 may provide command/address signals transferred from the channel CH.A to one of the memory devices A and B, and transmit and receive data to and from one of the memory devices A and B. In this instance, the memory device B may input and output the command/address signals and the data from and to the memory device A through the command/address/data pads arranged in the memory device A. Likewise, through the command/address/data pads arranged in the memory device C, the memory controller 12 may provide command/address signals transferred from the channel CH.C to one of the memory devices C and D, and transmit data to and receive data from one of the memory devices C and D. In this instance, the memory device D may input and output the command/address signals and the data from and to the memory device C through the command/address/data pads arranged in the memory device C.

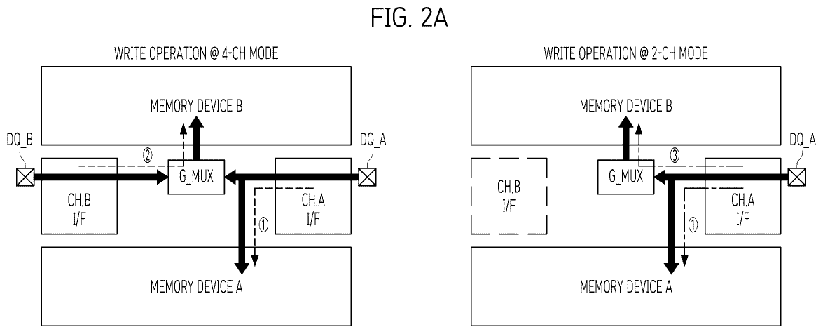

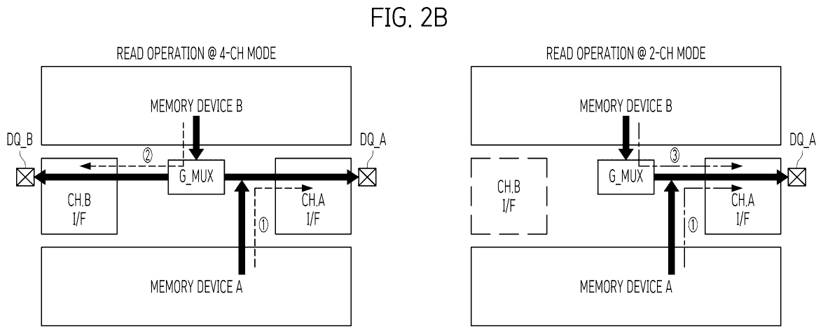

FIGS. 2A and 2B are block diagrams for describing a write operation and a read operation of one memory chip 14 in a 2-CH mode and a 4-CH mode. In FIGS. 2A and 2B, a data input/output operation during the write and read operations is illustrated.

In FIGS. 2A and 2B, channel interface regions CH.A I/F and CH.B I/F may be respectively coupled to data pads DQ_A and DQ_B, which are physically separate. To support both the 2-CH mode and the 4-CH mode, the memory device B may be coupled to the channel interface regions CH.A I/F and CH.B I/F via a multiplexer (i.e., a global multiplexer, G_MUX) for global input/output lines. That is, data to be written into the memory device B may be routed from the channel interface regions CH.A I/F and CH.B I/F through the global multiplexer G_MUX, and data to be read out from the memory device B may be routed to the channel interface regions CH.A I/F and CH.B I/F through the global multiplexer G_MUX.

Referring to FIG. 2A, in a write operation in the 4-CH mode, the memory devices A and B may independently receive data through their respective channel interface regions CH.A I/F and CH.B I/F. That is, the memory device A may receive the data through the channel interface region CH.A I/F from the data pad DQ_A, and the memory device B may receive the data through the channel interface region CH.B I/F from the data pad DQ_B. In contrast, in a write operation in the 2-CH mode, the memory devices A and B may commonly receive the data through the channel interface region CH.A I/F. That is, both memory devices A and B may receive the data through the channel interface region CH.A I/F from the data pad DQ_A.

As described above, during the write operation, the memory device A directly receives the data through the channel interface region CH.A I/F (see \textcircled{1}), while the memory device B receives the data either from the channel interface region CH.B I/F via the global multiplexer G_MUX (see \textcircled{2}) or from the channel interface region CH.A I/F via the global multiplexer G_MUX (see \textcircled{3}). Accordingly, the memory device B experiences a relatively greater delay in data transfer compared to the memory device A.

Referring to FIG. 2B, in a read operation in the 4-CH mode, the memory devices A and B may independently output data through their respective channel interface regions CH.A I/F and CH.B I/F. That is, the memory device A may output the data to the data pad DQ_A through the channel interface region CH.A I/F, and the memory device B may output the data to the data pad DQ_B through the channel interface region CH.B I/F. In contrast, in a read operation in the 2-CH mode, the memory devices A and B may commonly output the data through the channel interface region CH.A I/F. That is, both memory devices A and B may output the data to the data pad DQ_A through the channel interface region CH.A I/F.

As described above, during the read operation, the memory device A directly outputs the data through the channel interface region CH.A I/F (see \textcircled{1}), while the memory device B outputs the data either to the channel interface region CH.B I/F via the global multiplexer G_MUX (see \textcircled{2}) or to the channel interface region CH.A I/F via the global multiplexer G_MUX (see \textcircled{3}). Accordingly, the memory device B experiences a relatively greater delay in data transfer compared to the memory device A.

As a result, due to muxing delays and physical placement (i.e., routing) differences between the memory devices A and B in each channel mode, data skew may occur. That is, although the 2-CH and 4-CH modes provide flexibility in system design, they may cause performance degradation and complexity due to physical and structural constraints in each mode, and such issues may become more severe during high-speed operation.

Hereinafter, the present disclosure will describe a method of minimizing skew between signals input to and output from a first memory device and a second memory device, which selectively share a first data pad according to a channel mode in a memory chip.

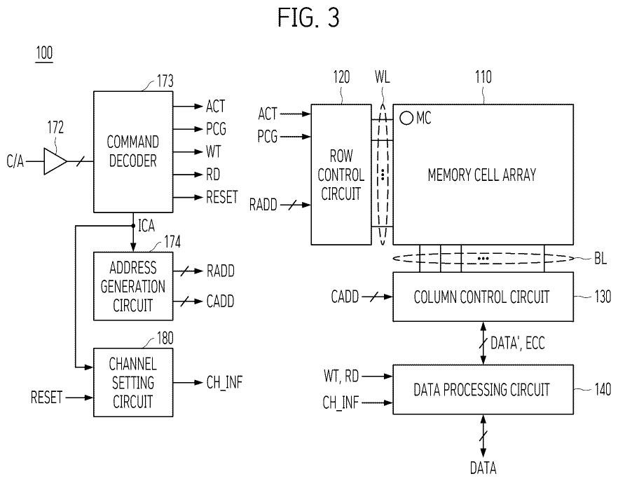

FIG. 3 is a block diagram of a memory device 100 in accordance with an embodiment of the present disclosure. The memory device 100 shown in FIG. 3 may correspond to any one of the memory devices A, B, C, or D in FIGS. 1A and 1B.

Referring to FIG. 3, the memory device 100 may include a memory cell array 110, a row control circuit 120, a column control circuit 130, a data processing circuit 140, a command/address reception circuit 172, a command decoder 173, an address generation circuit 174, and a channel setting circuit 180.

The memory cell array 110 may be a region where data is stored in the memory device 100, and may include a plurality of memory cells MC for storing the data. The plurality of memory cells MC may be coupled between a plurality of word lines WL and a plurality of bit lines BL arranged in an array. The memory cell array 110 may be coupled to the row control circuit 120 through the plurality of word lines WL and coupled to the column control circuit 130 through the plurality of bit lines BL. The plurality of word lines WL may extend in a first direction (e.g., a row direction) and may be sequentially disposed in a second direction (e.g., a column direction) perpendicular to the first direction. The memory cell array 110 may be composed of at least one bank. The number of banks or the number of memory cells MC may be determined depending on the capacity of the memory device 100. The memory cell array 110 may receive and store data DATA′ and an error correction code ECC from the column control circuit 130 during a write operation. During a read operation, the memory cell array 110 may output the stored data DATA′ and the stored error correction code ECC to the column control circuit 130. The data DATA′ may be defined as user data, the error correction code ECC may be referred to as parity data.

The command/address receiving circuit 172 may receive a command/address signal C/A from a memory controller. Depending on the type of memory device 100, a command and an address may be input through the same input terminals, or a command and an address may be input through separate input terminals. In FIG. 3, it is illustrated that the command and the address are input through the same input terminals. The command/address signal C/A may be formed of multiple bits.

The command decoder 173 may decode the command/address signal C/A received by the command/address receiving circuit 172 to generate an active command ACT, a precharge command PCG, a write command WT, a read command RD, and a reset command RESET. The active command ACT is a signal input when an active operation is instructed, the precharge command PCG is a signal input when a precharge operation is instructed, the write command WT is a signal input when a write operation is instructed, and the read command RD may be a signal input when a read operation is instructed. The reset command RESET may be provided to initialize the memory device 100. Depending on an embodiment, the command decoder 173 may decode the command/address signal C/A to additionally generate a refresh command for instructing a refresh operation and a mode setting command for instructing a mode register setting operation.

The address generation circuit 174 may classify an internal address ICA received from the command decoder 173 into a row address RADD and a column address CADD. The row address RADD may be an address for selecting one of the plurality of word lines WL, and the column address CADD may be an address for selecting some bit lines for performing a read operation or a write operation, from the plurality of bit lines BL. Each of the row address RADD and the column address CADD may be formed of multiple bits.

The channel setting circuit 180 may generate a channel mode signal CH_INF by monitoring the internal address signal ICA in response to the reset command RESET. For example, the channel setting circuit 180 may set the channel mode signal CH_INF based on a specific bit (e.g., a least significant bit (LSB)) of the internal address signal ICA at a timing when the reset command RESET transitions from a logic low level to a logic high level.

The channel mode signal CH_INF may be a signal used to designate a configured channel mode and may be used to distinguish between a 4-CH mode and a 2-CH mode described in FIGS. 1A and 1B. For example, it is assumed that a first memory device and a second memory device are disposed in a single memory chip. As shown in FIG. 1A, in the 4-CH mode in which the first memory device inputs and outputs data through a first data pad and the second memory device inputs and outputs data through a second data pad, the channel mode signal CH_INF may be stored at a logic high level. As shown in FIG. 1B, in the 2-CH mode in which the first and second memory devices share the first data pad for data input/output, the channel mode signal CH_INF may be stored at a logic low level. In this instance, the channel setting circuit 180 of the first memory device, which includes the shared first data pad, may store the channel mode signal CH_INF designating the set channel mode (i.e., 2-CH mode or 4-CH mode), whereas the channel setting circuit 180 of the second memory device which does not include the shared first data pad, may store the channel mode signal CH_INF designating the 4-CH mode. That is, the channel mode signal CH_INF stored in the channel setting circuit 180 of the second memory device may be fixed at a logic high level.

The row control circuit 120 may perform the active operation of activating a row selected by the row address RADD in response to the active command ACT, and may perform the precharge operation of precharging the activated row in response to the precharge command PCG.

The column control circuit 130 may select some bit lines of the plurality of bit lines BL of the memory cell array 110 according to the column address CADD, perform a read operation of reading the data DATA′ and the error correction code ECC from the memory cells MC through the selected bit lines in response to the read command RD, or perform a write operation of writing the data DATA′ and the error correction code ECC to the memory cells MC through the selected bit lines in response to the write command WT.

The data processing circuit 140 may latch data DATA provided from the memory controller in response to the write command WT, and may output the latched data DATA′ and the error correction code ECC generated using the data DATA to the column control circuit 130 (i.e., the memory cell array 110). The data processing circuit 140 may latch the data DATA′ and the error correction code ECC output from the column control circuit 130 in response to the read command RD, and may correct an error in the latched data DATA′ using the latched error correction code ECC to transmit error-corrected data DATA to the memory controller. In the embodiment of the present disclosure, the data processing circuit 140 may adjust a timing of latching the data DATA and DATA′ based on the channel mode signal CH_INF.

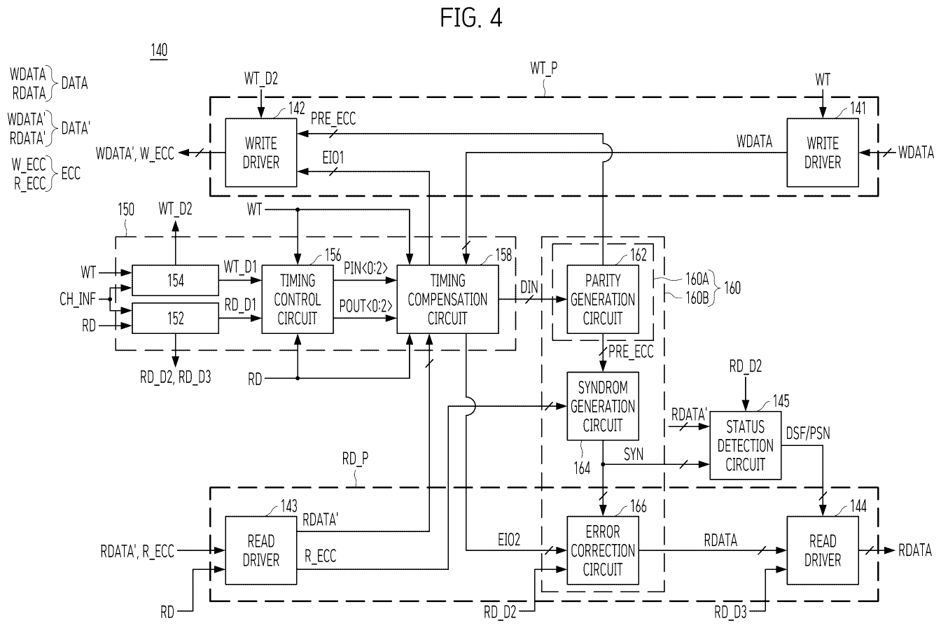

FIG. 4 is a detailed configuration diagram illustrating the data processing circuit 140 of FIG. 3 in accordance with an embodiment of the present disclosure.

Referring to FIG. 4, the data processing circuit 140 may include a write path WT_P, a read path RD_P, a data latch circuit 150, and an error correction code (ECC) engine 160.

In the following description, depending on write and read operations, the data DATA and DATA′ input to and output from the data processing circuit 140 will be referred to as write data WDATA and WDATA′ and read data RDATA and RDATA′, respectively. The error correction code ECC will also be referred to as a write error correction code W_ECC and a read error correction code R_ECC. Although FIG. 4 illustrates the data processing circuit 140 as directly receiving and operating based on a read command RD and a write command WT, the embodiments are not limited thereto. In some embodiments, the read command RD may be adjusted based on timing parameters defined with respect to the read operation (for example, in related specifications), and the write command WT may be adjusted similarly based on timing parameters defined with respect to the write operation. For example, instead of the read command RD and the write command WT, read and write signals with adjusted timing or activation periods may be used.

The write path WT_P is a path for receiving write data WDATA from the memory controller during a write operation and transferring write data WDATA′ and write error correction code W_ECC to the memory cell array 110. For example, the write path WT_P may include a first write driver 141 and a second write driver 142. The first write driver 141 may receive the write data WDATA in response to the write command WT, and the second write driver 142 may write data WDATA′ and write error correction code W_ECC by driving first delayed data EIO1 and a preliminary error correction code PRE_ECC in response to a second delayed write signal WT_D2.

The read path RD_P is a path for receiving read data RDATA′ and read error correction code R_ECC read from the memory cell array 110 during a read operation, and outputting error-corrected data RDATA to the memory controller. For example, the read path RD_P may include a first read driver 143, an error correction circuit 166, and a second read driver 144. The first read driver 143 may receive the read data RDATA′ and the read error correction code R_ECC in response to the read command RD. The error correction circuit 166 may correct an error in second delayed data EIO2 in response to a second delayed read signal RD_D2. The second read driver 144 may output the error-corrected data RDATA in response to a third delayed read signal RD_D3.

In some embodiments, the drivers 141 through 144 may be implemented with repeaters to enhance a signal strength of a transmission-side signal, thereby recognizing the transmission-side signal at a reception side, and may not be essential components. Depending on a length of input/output lines of each driver, a signal strength transmitted through those lines, and the process, voltage, temperature (PVT) condition, the drivers 141 through 144 may be optionally omitted.

The data latch circuit 150 may generate a first delayed write signal WT_D1 by variably delaying the write command WT based on the channel mode signal CH_INF, latch the write data WDATA provided from the first write driver 141 in response to the write command WT, and output the latched data as the first delayed data EIO1 in response to the first delayed write signal WT_D1. The data latch circuit 150 may also generate a first delayed read signal RD_D1 by variably delaying the read command RD based on the channel mode signal CH_INF, latch the read data RDATA′ provided from the first read driver 143 in response to the read command RD, and output the latched read data as the second delayed data EIO2 in response to the first delayed read signal RD_D1. Hereinafter, the first delayed data EIO1 and the second delayed data EIO2 may be collectively referred to as delayed data EIO. The data latch circuit 150 may also generate the second delayed write signal WT_D2, the second delayed read signal RD_D2, and the third delayed read signal RD_D3 based on the first delayed write signal WT_D1 and the first delayed read signal RD_D1.

More specifically, the data latch circuit 150 may include a first delay adjustment circuit 152, a second delay adjustment circuit 154, a timing control circuit 156, and a timing compensation circuit 158.

The first delay adjustment circuit 152 may delay the read command RD by either a first channel delay or a second channel delay based on the channel mode signal CH_INF to generate the first delayed read signal RD_D1. The first delay adjustment circuit 152 may generate the second delayed read signal RD_D2 by delaying the first delayed read signal RD_D1 by a first delay time, and generate the third delayed read signal RD_D3 by delaying the second delayed read signal RD_D2 by a second delay time. The first delay time and the second delay time may be set based on read timing parameters defined with respect to the read operation (for example, in a related specification).

The second delay adjustment circuit 154 may delay the write command WT by either a third channel delay or a fourth channel delay based on the channel mode signal CH_INF to generate the first delayed write signal WT_D1. The second delay adjustment circuit 154 may generate the second delayed write signal WT_D2 by delaying the first delayed write signal WT_D1 by a third delay time. The third delay time may be set based on write timing parameters defined with respect to the write operation (for example, in a related specification).

The timing control circuit 156 may generate input control signals PIN<0:2> in response to the write command WT or read command RD, and generate output control signals POUT<0:2> based on the first delayed write signal WT_D1 or the first delayed read signal RD_D1.

The timing compensation circuit 158 may generate the first delayed data EIO1 in response to the write command WT by delaying the write data WDATA in a pipeline process according to the input control signals PIN<0:2> and the output control signals POUT<0:2>. The timing compensation circuit 158 may sequentially latch the write data WDATA according to the input control signals PIN<0:2> and sequentially output the first delayed data EIO1 according to the output control signals POUT<0:2>. The timing compensation circuit 158 may generate the second delayed data EIO2 in response to the read command RD by delaying the read data RDATA′ in a pipeline process according to the input control signals PIN<0:2> and the output control signals POUT<0:2>. The timing compensation circuit 158 may sequentially latch the read data RDATA′ according to the input control signals PIN<0:2> and sequentially output the second delayed data EIO2 according to the output control signals POUT<0:2>. Additionally, the timing compensation circuit 158 may transfer the write data WDATA as internal data DIN to the ECC engine 160 in response to the write command WT, or transfer the read data RDATA′ as the internal data DIN to the ECC engine 160 in response to the read command RD.

The ECC engine 160 may generate the preliminary error correction code PRE_ECC using the internal data DIN during the write operation, and may output the error-corrected data RDATA by correcting an error in the second delayed data EIO2 using the preliminary error correction code PRE_ECC and the read the error correction code R_ECC during the read operation. The ECC engine 160 may be configured to perform an ECC operation using LDPC (Low Density Parity Check) code, BCH (Bose, Chaudhri, Hocquenghem) code, turbo code, Reed-Solomon code, convolution code, RSC (Recursive Systematic Code), and a coded modulation such as TCM (Trellis-Coded Modulation) and BCM (Block Coded Modulation).

More specifically, the ECC engine 160 may include a parity generation circuit 162, a syndrome generation circuit 164, and the error correction circuit 166. The parity generation circuit 162 may be referred to as an ECC encoder 160A, and the parity generation circuit 162, the syndrome generation circuit 164, and the error correction circuit 166 may be referred to as an ECC decoder 160B.

The parity generation circuit 162 may generate the preliminary error correction code PRE_ECC by performing an ECC operation on the internal data DIN. The syndrome generation circuit 164 may generate a syndrome SYN by comparing the preliminary error correction code PRE_ECC and the read error correction code R_ECC. The error correction circuit 166 may identify a position of at least one error bit in the second delayed data EIO2 based on the syndrome SYN and output error-corrected data RDATA by correcting an error by inverting the identified error bit of the second delayed data EIO2. The error correction circuit 166 may correct the error in the second delayed data EIO2 in synchronization with the second delayed read signal RD_D2 and output the error-corrected data RDATA. In this instance, a time required to compute the preliminary error correction code PRE_ECC may be referred to as a first computation time, a time required to compute the preliminary error correction code PRE_ECC and the syndrome SYN may be referred to as a second computation time, and a time required for the error correction performed by the error correction circuit 166 may be referred to as a third computation time. The second computation time may be greater than the first computation time due to the relatively larger amount of information processed.

In an embodiment, the data processing circuit 140 may further include a status detection circuit 145. The status detection circuit 145 may generate a decoding status flag and/or poison flag (DSF/PSN) based on the read data RDATA′ and/or the syndrome SYN in synchronization with the second delayed read signal RD_D2. For example, the status detection circuit 145 may generate the decoding status flag DSF indicating a correctable error, an uncorrectable error, or no error, depending on the number of high bits in the syndrome SYN. For another example, the status detection circuit 145 may generate the poison flag PSN when the read data RDATA′ matches a preset pattern. The status detection circuit 145 may generate the decoding status flag DSF and/or the poison flag PSN in synchronization with the second delayed read signal RD_D2 and provide them to the second read driver 144. The second read driver 144 may output the error-corrected data RDATA by inserting the decoding status flag DSF and/or the poison flag PSN into the error-corrected data RDATA in response to the third delayed read signal RD_D3. In some embodiments, a separate driver may be further provided to output the decoding status flag DSF and/or the poison flag PSN as separate signals through separate lines in response to the third delayed read signal RD_D3.

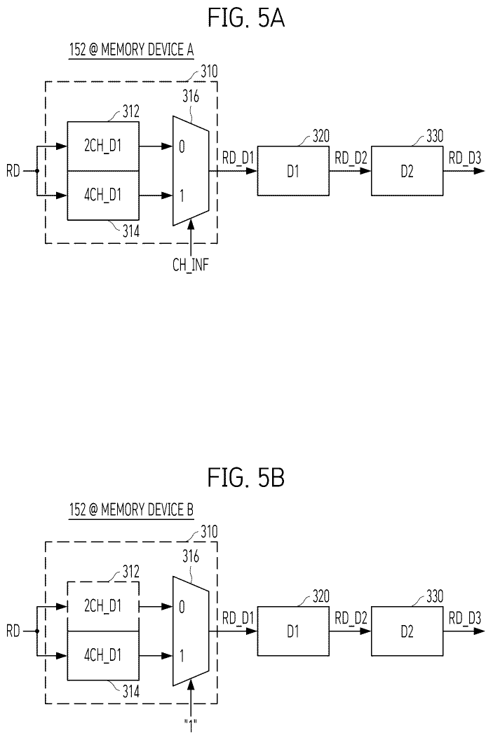

FIGS. 5A and 5B are detailed configuration diagrams illustrating the first delay adjustment circuit 152 of FIG. 4, in accordance with an embodiment of the present disclosure. In FIG. 5A, a configuration of the first delay adjustment circuit 152 in the first memory device A which includes the shared first data pad is shown. In FIG. 5B, a configuration of the first delay adjustment circuit 152 in the second memory device B which does not include the shared first data pad is shown.

Referring to FIG. 5A, the first delay adjustment circuit 152 of the first memory device A may include a variable delay 310, a first fixed delay 320, and a second fixed delay 330.

The variable delay 310 may generate the first delayed read signal RD_D1 by delaying the read command RD by one of the first channel delay 2CH_D1 and the second channel delay 4CH_D1 according to the channel mode signal CH_INF.

For example, the variable delay 310 may include a first delay 312, a second delay 314, and a selector 316.

The first delay 312 may have the first channel delay 2CH_D1 which replicates a data transfer delay in a read operation under a 2-CH mode, and delays the read command RD by the first channel delay 2CH_D1. The second delay 314 may have the second channel delay 4CH_D1 which replicates a data transfer delay in a read operation under a 4-CH mode, and delays the read command RD by the second channel delay 4CH_D1. For instance, the first and second delays 312 and 314 may include a plurality of resistor elements coupled in series, and the number of resistor elements coupled in series may be determined according to a test mode signal to set the delay time. In the 2-CH mode, the timing difference in data transfer between the memory devices A and B is greater than the timing difference in the 4-CH mode. Therefore, in an embodiment of the present disclosure, for compensation, the first channel delay 2CH_D1 of the first memory device A may be set to be greater than the second channel delay 4CH_D1 of the first memory device A.

The selector 316 may output the first delayed read signal RD_D1 by selecting one of an output of the first delay 312 and an output of the second delay 314 according to the channel mode signal CH_INF. The selector 316 may output the first delayed read signal RD_D1 by selecting the output of the first delay 312 when the channel mode signal CH_INF at a logic low level, and by selecting the output of the second delay 314 when the channel mode signal CH_INF at a logic high level.

The first fixed delay 320 may generate the second delayed read signal RD_D2 by delaying the first delayed read signal RD_D1 by the first delay time D1. In this instance, the first delay time D1 may be set depending on the second computation time required for generating the preliminary error correction code PRE_ECC and computing the syndrome SYN.

The second fixed delay 330 may generate the third delayed read signal RD_D3 by delaying the second delayed read signal RD_D2 by a second delay time D2. In this instance, the second delay time D2 may be set depending on the third computation time required for the error correction performed by the error correction circuit 166.

Referring to FIG. 5B, the first delay adjustment circuit 152 of the second memory device B may have the same configuration as that of the first delay adjustment circuit 152 of the first memory device A, and may include a variable delay 310, a first fixed delay 320, and a second fixed delay 330. Unlike the first memory device A, the variable delay 310 of the second memory device B may always output an output of the second delay 314 as the first delayed read signal RD_D1, according to the channel mode signal CH_INF fixed at a logic high level.

With this configuration, the first delay adjustment circuit 152 of the first memory device A, which includes the shared first data pad, may output the first delayed read signal RD_D1 with different delay times depending on whether the configured channel mode is 2-CH or 4-CH. On the contrary, the first delay adjustment circuit 152 of the second memory device B, which does not include the shared first data pad, may always output the first delayed read signal RD_D1 with the second channel delay 4CH_D1.

In an embodiment of the present disclosure, since the timing difference in data transfer between the memory devices A and B in the 2-CH mode is greater than the timing difference in the 4-CH mode, the first channel delay 2CH_D1 may be set to be greater than the second channel delay 4CH_D1 in each of the memory devices A and B for compensation. Furthermore, since the second memory device B experiences additional data transfer delay due to the global multiplexer G_MUX, the second channel delay 4CH_D1 in the first memory device A may be set to be greater than that of the second memory device B by the amount of delay introduced by the global multiplexer G_MUX. Likewise, the first channel delay 2CH_D1 in the first memory device A may also be set to be greater than that of the second memory device B by at least the delay amount introduced by the global multiplexer G_MUX.

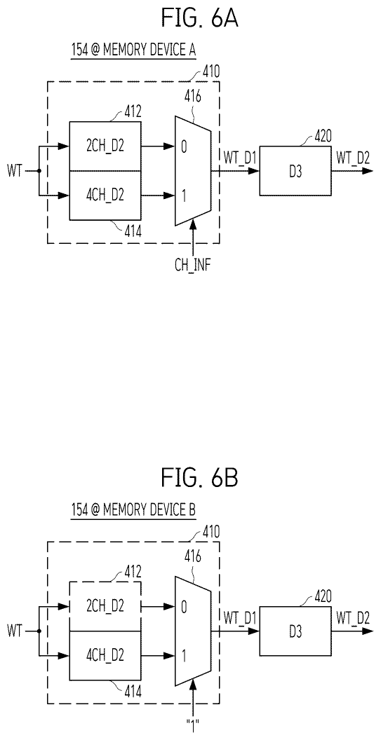

FIGS. 6A and 6B are detailed configuration diagrams of the second delay adjustment circuit 154 of FIG. 4, in accordance with an embodiment of the present disclosure. In FIG. 6A, a configuration of the second delay adjustment circuit 154 in the first memory device A which includes the shared first data pad is shown. In FIG. 6B, a configuration of the second delay adjustment circuit 154 in the second memory device B which does not include the shared first data pad is shown.

Referring to FIG. 6A, the second delay adjustment circuit 154 of the first memory device A may include a variable delay 410 and a fixed delay 420.

The variable delay 410 may generate the first delayed write signal WT_D1 by delaying the write command WT by one of the third channel delay 2CH_D2 and the fourth channel delay 4CH_D2 according to the channel mode signal CH_INF.

For example, the variable delay 410 may include a first delay 412, a second delay 414, and a selector 416.

The first delay 412 may have the third channel delay 2CH_D2 which may replicate a data transfer delay in a write operation under a 2-CH mode, and may delay the write command WT by the third channel delay 2CH_D2. The second delay 414 may have the fourth channel delay 4CH_D2 which replicates a data transfer delay in a write operation under a 4-CH mode, and delays the write command WT by the fourth channel delay 4CH_D2. In the 2-CH mode, the timing difference in data transfer between the memory devices A and B is greater than in the 4-CH mode. Therefore, in an embodiment of the present disclosure, for compensation, the third channel delay 2CH_D2 may be set to be greater than the fourth channel delay 4CH_D2. The selector 416 may output the first delayed write signal WT_D1 by selecting one of an output of the first delay 412 and an output of the second delay 414 according to the channel mode signal CH_INF. The selector 416 may output the first delayed write signal WT_D1 by selecting the output of the first delay 412 when the channel mode signal CH_INF is at a logic low level, and by selecting the output of the second delay 414 when the channel mode signal CH_INF is at a logic high level.

The fixed delay 420 may generate the second delayed write signal WT_D2 by delaying the first delayed write signal WT_D1 by the third delay time D3. In this instance, the third delay time D3 may be set depending on the first computation time required to generate the preliminary error correction code PRE_ECC.

Referring to FIG. 6B, the second delay adjustment circuit 154 of the second memory device B may have the same configuration as that of the second delay adjustment circuit 154 of the first memory device A, and may include a variable delay 410 and a fixed delay 420. Unlike the first memory device A, the variable delay 410 of the second memory device B may always output an output of the second delay 414 as the first delayed write signal WT_D1, according to the channel mode signal CH_INF fixed at a logic high level.

With this configuration, the second delay adjustment circuit 154 of the first memory device A, which includes the shared first data pad, may output the first delayed write signal WT_D1 with different delay times depending on whether the configured channel mode is 2-CH or 4-CH. On the contrary, the second delay adjustment circuit 154 of the second memory device B, which does not include the shared first data pad, may always output the first delayed write signal WT_D1 with the fourth channel delay 4CH_D2.

In an embodiment of the present disclosure, since the timing difference in data transfer between the memory devices A and B in the 2-CH mode is greater than that in the 4-CH mode, the third channel delay 2CH_D2 may be set to be greater than the fourth channel delay 4CH_D2 in each of the memory devices A and B for compensation. Furthermore, since the second memory device B experiences additional data transfer delay due to the global multiplexer G_MUX, the fourth channel delay 4CH_D2 in the first memory device A may be set to be greater than that of the second memory device B by the amount of delay introduced by the global multiplexer G_MUX. Likewise, the third channel delay 2CH_D2 in the first memory device A may also be set to be greater than that of the second memory device B by at least the delay amount introduced by the global multiplexer G_MUX.

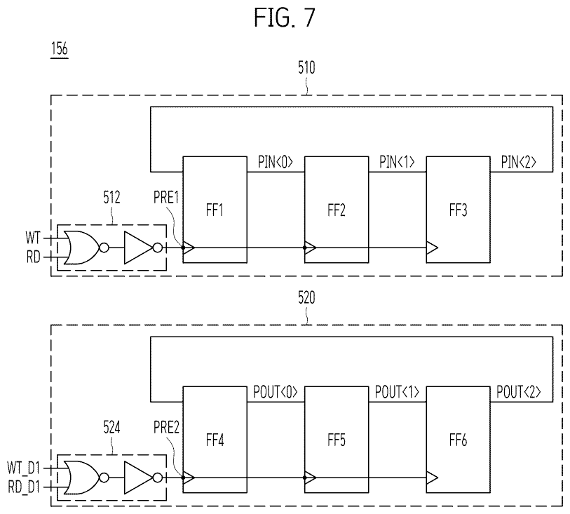

FIG. 7 is a detailed circuit diagram illustrating the timing control circuit 156 of FIG. 4 in accordance with an embodiment of the present disclosure.

Referring to FIG. 7, the timing control circuit 156 may include an input control circuit 510 and an output control circuit 520.

The input control circuit 510 may generate the input control signals PIN<0:2> in response to the write command WT and the read command RD. The input control circuit 510 may include a first control signal generator 512 and first to third flip-flops FF1 to FF3.

The first control signal generator 512 may perform a logical OR operation on the write command WT and the read command RD to generate a first preliminary control signal PRE1. The first control signal generator 512 may activate and output the first preliminary control signal PRE1 when either the write command WT or the read command RD is input. For example, the first control signal generator 512 may be implemented with a NOR gate and an inverter.

The first to third flip-flops FF1 through FF3 may receive the first preliminary control signal PRE1 as a clock input, and may be connected in series to receive an output of the previous stage as an input. The first flip-flop FF1 may receive an output of the third flip-flop FF3 as an input. With this configuration, the first to third flip-flops FF1 to FF3 may operate as a shift register, shifting the output of the previous stage to the next stage each time the first preliminary control signal PRE1 is activated. The input control signals PIN<0:2> may be output from respective output terminals of the first to third flip-flops FF1 to FF3.

The output control circuit 520 may generate the output control signals POUT<0:2> in response to the first delayed write signal WT_D1 and the first delayed read signal RD_D1. The output control circuit 520 may include a second control signal generator 524 and fourth to sixth flip-flops FF4 to FF6.

The second control signal generator 524 may perform a logical OR operation on the first delayed write signal WT_D1 and the first delayed read signal RD_D1 to generate a second preliminary control signal PRE2. The second control signal generator 524 may activate and output the second preliminary control signal PRE2 when either the first delayed write signal WT_D1 or the first delayed read signal RD_D1 is activated. For example, the second control signal generator 524 may be implemented with a NOR gate and an inverter.

The fourth to sixth flip-flops FF4 to FF6 may receive the second preliminary control signal PRE2 as a clock input, and may be connected in series to receive an output of the previous stage as an input. The fourth flip-flop FF4 may receive an output of the sixth flip-flop FF6 as an input. With this configuration, the fourth to sixth flip-flops FF4 to FF6 may operate as a shift register, shifting the output of the previous stage to the next stage each time the second preliminary control signal PRE2 is activated. The output control signals POUT<0:2> may be output from respective output terminals of the fourth to sixth flip-flops FF4 to FF6.

Although not shown in the drawings, the first to sixth flip-flops FF1 to FF6 may be initialized in response to a reset signal. For example, when the reset signal is input at a logic high level, the first to sixth flip-flops FF1 to FF6 may initialize all of the input control signals PIN<0:2> and the output control signals POUT<0:2> to logic low levels.

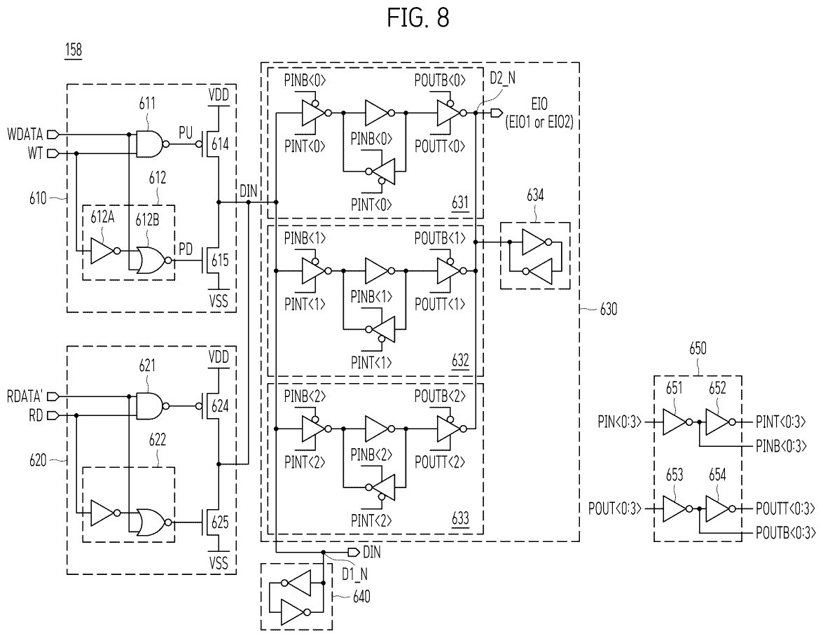

FIG. 8 is a detailed circuit diagram illustrating the timing compensation circuit 158 of FIG. 4.

Referring to FIG. 8, the timing compensation circuit 158 may include a write driving circuit 610, a read driving circuit 620, a pipeline register 630, an internal data latch 640, and a pipeline control circuit 650.

The write driving circuit 610 may generate the internal data DIN by driving the write data WDATA in response to the write command WT. The write driving circuit 610 may include a pull-up control circuit 611, a pull-down control circuit 612, a pull-up driver 614, and a pull-down driver 615. The pull-up control circuit 611 may generate a pull-up driving signal PU by inverting the write data WDATA in response to the write command WT. The pull-up control circuit 611 may be implemented with a NAND gate that performs a logic NAND operation on the write command WT and the write data WDATA. The pull-down control circuit 612 may generate a pull-down driving signal PD by inverting the write data WDATA in response to the write command WT. The pull-down control circuit 612 may include an inverter 612A for inverting the write data WDATA and a NOR gate 612B that performs a logic NOR operation on an output of the inverter 612A and the write data WDATA to output the pull-down driving signal PD. The pull-up driver 614 may be turned on according to the pull-up driving signal PU to drive the internal data DIN to a power supply voltage (VDD) level. The pull-down driver 615 may be turned on according to the pull-down driving signal PD to drive the internal data DIN to a ground voltage (VSS) level.

With the above configuration, when the write command WT and the write data WDATA of a logic high level are input, the write driving circuit 610 may output the pull-up driving signal PU and the pull-down driving signal PD at logic low levels. As a result, the pull-up driver 614 may be turned on to drive the internal data DIN to the power supply voltage (VDD) level. In contrast, when the write command WT and the write data WDATA of a logic low level are input, the write driving circuit 610 may output the pull-up driving signal PU and the pull-down driving signal PD at logic high levels. As a result, the pull-down driver 615 may be turned on to drive the internal data DIN to the ground voltage (VSS) level.

The read driving circuit 620 may generate the internal data DIN by driving read data RDATA in response to the read command RD. The read driving circuit 620 may include a pull-up control circuit 621, a pull-down control circuit 622, a pull-up driver 624, and a pull-down driver 625. The configuration of the read driving circuit 620 may be substantially the same as that of the write driving circuit 610, except for the input/output signals. That is, when the read data RDATA of a logic high level is input with the read command RD, the internal data DIN may be driven to the power supply voltage (VDD) level. In contrast, when the read data RDATA of a logic low level is input with the read command RD, the internal data DIN may be driven to the ground voltage (VSS) level.

The internal data latch 640 may be connected to a node D1_N from which the internal data DIN is output, and may latch the internal data DIN.

The pipeline control circuit 650 may generate multiple control signals PINB<0:2>, PINT<0:2>, POUTB<0:2>, and POUTT<0:2> based on the input control signals PIN<0:2> and the output control signals POUT<0:2>.

The pipeline control circuit 650 may include first to fourth inverter blocks 651 to 654. Although the inverters 651 to 654 are illustrated as single inverters in FIG. 8, in accordance with embodiments each of the represented inverters 651 to 654 may be composed of a plurality of inverters corresponding to the number of input or output control signals (e.g., three). The first inverter 651 may generate negative input control signals PINB<0:2> by inverting the input control signals PIN<0:2>, and the second inverter 652 may generate positive input control signals PINT<0:2> by inverting the negative input control signals PINB<0:2>. The third inverter 653 may generate negative output control signals POUTB<0:2> by inverting the output control signals POUT<0:2>, and the fourth inverter 654 may generate positive output control signals POUTT<0:2> by inverting the POUTB<0:2> signals.

The pipeline register 630 may have a multi-stage pipeline structure, and may output the delayed data EIO by processing the internal data DIO, which are sequentially input according to the write command WT, in a pipeline process according to the control signals PINB<0:2>, PINT<0:2>, POUTB<0:2>, and POUTT<0:2>. Although the pipeline register 630 in FIG. 8 is illustrated with a three-stage pipeline structure 631 to 633 as an example, the scope of the embodiments of the present disclosure is not limited thereto and may be implemented with more than three stages depending on design choices. The first-stage pipeline 631 may receive and latch the internal data DIN according to the first negative and positive input control signals PINB<0> and PINT<0>, and may output the latched data as the delayed data EIO according to the first negative and positive output control signals POUTB<0> and POUTT<0>. The second-stage pipeline 632 may receive and latch the internal data DIN according to the second negative and positive input control signals PINB<1> and PINT<1>, and may output the latched data as the delayed data EIO according to the second negative and positive output control signals POUTB<1> and POUTT<1>. The third-stage pipeline 633 may receive and latch the internal data DIN according to the third negative and positive input control signals PINB<2> and PINT<2>, and may output the latched data as the delayed data EIO according to the third negative and positive output control signals POUTB<2> and POUTT<2>.

The pipeline register 630 may further include a delayed data latch 634 connected to a node D2_N from which the delayed data EIO is output, and may latch the delayed data EIO. The delayed data EIO may be provided as the first delayed data EIO1 or the second delayed data EIO2.

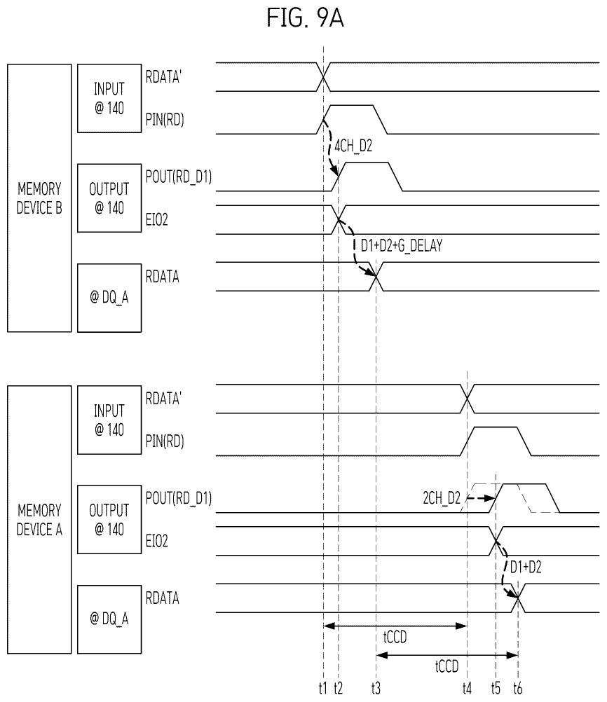

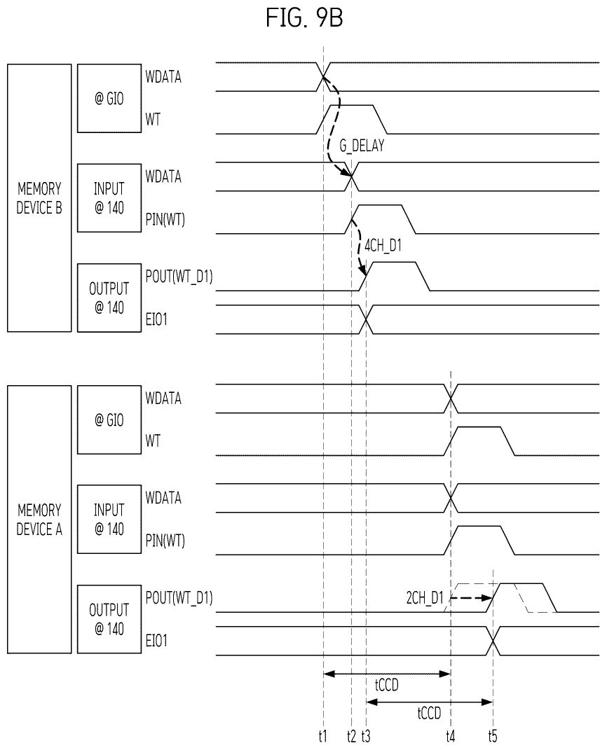

Hereinafter, referring to FIGS. 9A and 9B, an operation of memory devices within a memory chip will be explained.

FIGS. 9A and 9B are timing diagrams for describing an operation of memory devices within a memory chip in accordance with an embodiment of the present disclosure.

Referring to FIG. 9A, a read operation of the memory devices A and B within the memory chip in the 2-CH mode is illustrated. In the read operation under the 2-CH mode, the memory devices A and B may commonly output data through the data pad DQ_A. As an example, it is assumed that the read command RD is first provided to the memory device B from the memory controller, and is then provided to the memory device A after a preset time tCCD. In this instance, the preset time tCCD may be a minimum required interval between consecutive read or write commands for different columns.

At time t1, in response to the read command RD, the read data RDATA′ and read error correction code R_ECC are read out from the memory cell array 110 of the memory device B. The data processing circuit 140 of the memory device B may latch the read data RDATA′ in response to the read command RD as the input control signal PIN (“INPUT @ 140”).

As described in FIG. 5B, the first delay adjustment circuit 152 of the memory device B may delay the read command RD by the second channel delay 4CH_D1, according to the channel mode signal CH_INF fixed at a logic high level, and generate the first delayed read signal RD_D1. At time t2, the data processing circuit 140 of the memory device B may use the first delayed read signal RD_D1 as the output control signal POUT to output the latched data as the second delayed data EIO2 (“OUTPUT @ 140”).

Furthermore, the parity generation circuit 162 of the memory device B may generate the preliminary error correction code PRE_ECC using the read data RDATA′. The syndrome generation circuit 164 may compare the preliminary error correction code PRE_ECC with the read error correction code R_ECC to generate the syndrome SYN. The error correction circuit 166 may correct an error in the second delayed data EIO2 based on the syndrome SYN and output the error-corrected data RDATA. The second read driver 144 may output the error-corrected data RDATA in response to the third delayed read signal RD_D3. Thereafter, the error-corrected data RDATA may be output to the data pad DQ_A through the global multiplexer G_MUX. Accordingly, at time t3, which is delayed from t2 by the first delay time D1, the second delay time D2, and a delay time G_DELAY due to the global multiplexer G_MUX, the error-corrected data RDATA may be output from the memory device B through the data pad DQ_A (“@ DQ_A”).

Subsequently, at time t4, in response to the read command RD, the read data RDATA′ and the read error correction code R_ECC are read out from the memory cell array 110 of the memory device A. The data processing circuit 140 of the memory device A may latch the read data RDATA′ in response to the read command RD as the input control signal PIN (“INPUT @ 140”).

As described in FIG. 5A, the first delay adjustment circuit 152 of the memory device A may delay the read command RD by the first channel delay 2CH_D1, according to the channel mode signal CH_INF at a logic low level in the 2-CH mode, and may generate the first delayed read signal RD_D1. At time t5, the data processing circuit 140 of the memory device A may use the first delayed read signal RD_D1 as the output control signal POUT to output the latched data as the second delayed data EIO2 (“OUTPUT @ 140”).

Additionally, the parity generation circuit 162 of the memory device A may generate the preliminary error correction code PRE_ECC using the read data RDATA′. The syndrome generation circuit 164 may compare the preliminary error correction code PRE_ECC with the read error correction code R_ECC to generate the syndrome SYN. The error correction circuit 166 may correct an error in the second delayed data EIO2 based on the syndrome SYN and output the error-corrected data RDATA. The second read driver 144 may output the error-corrected data RDATA in response to the third delayed read signal RD_D3. Thereafter, the error-corrected data RDATA may be output to the data pad DQ_A without passing through the global multiplexer G_MUX. Accordingly, at time t6, which is delayed from t5 by the first delay time D1 and the second delay time D2, the error-corrected data RDATA may be output from the memory device A through the data pad DQ_A (“@ DQ_A”)

Referring to FIG. 9B, a write operation of the memory devices A and B within the memory chip in the 2-CH mode is illustrated. In the write operation under the 2-CH mode, the memory devices A and B may commonly receive data through the data pad DQ_A. As an example, it is assumed that the write command WT and the write data WDATA are first provided to the memory device B from the memory controller, and then provided to the memory device A after a preset time tCCD.

At time t1, the write command WT and the write data WDATA provided from the memory controller may be transferred through the data pad DQ_A and loaded onto the global input/output line GIO (“@ GIO”).

In this instance, the write command WT and the write data WDATA provided to the memory device B may be delayed by the global multiplexer G_MUX before reaching the data processing circuit 140 of the memory device B. At time t2, the data processing circuit 140 of the memory device B may latch the write data WDATA in response to the write command WT as the input control signal PIN (“INPUT @ 140”).

As described in FIG. 6B, the second delay adjustment circuit 154 of the memory device B may delay the write command WT by the fourth channel delay 4CH_D2 according to the channel mode signal CH_INF fixed at a logic high level, and generate the first delayed write signal WT_D1. At time t3, the data processing circuit 140 of the memory device B may use the first delayed write signal WT_D1 as the output control signal POUT to output the latched data as the first delayed data EIO1 (“OUTPUT @ 140”). Meanwhile, the parity generation circuit 162 of the memory device B may generate the preliminary error correction code PRE_ECC using the write data WDATA. Thereafter, the second write driver 142 may provide the first delayed data EIO1 and the preliminary error correction code PRE_ECC as the write data WDATA′ and the write error correction code W_ECC to the memory cell array 110 in response to the second delayed write signal WT_D2.

At time t4, the write command WT and the write data WDATA provided from the memory controller may again be transferred through the data pad DQ_A and loaded onto the global input/output line GIO (“@ GIO”). In this instance, the write command WT and the write data WDATA provided to the memory device A may be transferred to the data processing circuit 140 of the memory device A without passing through the global multiplexer G_MUX, that is, without the delay time G_DELAY. The data processing circuit 140 of the memory device A may latch the write data WDATA in response to the write command WT as the input control signal PIN (“INPUT @ 140”).

As described in FIG. 6A, the second delay adjustment circuit 154 of the memory device A may delay the write command WT by the third channel delay 2CH_D2 according to the channel mode signal CH_INF at a logic low level in the 2-CH mode, and may generate the first delayed write signal WT_D1. At time t5, the data processing circuit 140 of the memory device A may use the first delayed write signal WT_D1 as the output control signal POUT to output the latched data as first delayed data EIO1 (“OUTPUT @ 140”).

Furthermore, the parity generation circuit 162 of the memory device A may generate the preliminary error correction code PRE_ECC using the write data WDATA. Thereafter, the second write driver 142 may provide the first delayed data EIO1 and the preliminary error correction code PRE_ECC as the write data WDATA′ and the write error correction code W_ECC to the memory cell array 110 in response to the second delayed write signal WT_D2.

As described above, in the embodiment of the present disclosure, a larger channel delay may be applied to the memory device A, compared to the memory device B which experiences longer data transfer time due to the delay time G_DELAY of the global multiplexer G_MUX during the read or write operations. Accordingly, even when the timing of read/write commands and data provided to the memory devices A and B is misaligned due to the delay time G_DELAY of the global multiplexer G_MUX, the preset time tCCD may still be ensured. Therefore, timing margin for the ECC operations may be improved, ECC reliability may be enhanced, and physical/structural timing differences may be optimized while maintaining design flexibility.

While the embodiments of the present disclosure have been described with respect to the specific embodiments, it will be apparent to those skilled in the art that various changes and modifications may be made without departing from the spirit and scope of the invention as defined in the following claims. Furthermore, the embodiments may be combined to form additional embodiments.

What is claimed is:

1. A memory system comprising first and second memory devices configured to selectively share a first data pad based on a channel mode, each of the first and second memory devices comprising:
a data latch circuit configured to
variably delay a read signal according to a channel mode signal corresponding to the channel mode to generate a first delayed read signal,
latch read data output from a memory cell region according to the read signal, and
output the latched read data as delayed data according to the first delayed read signal; and
an error correction code (ECC) engine configured to correct an error in the delayed data based on a read error correction code read from the memory cell region to generate error-corrected data.

2. The memory system of claim 1,
wherein the first memory device includes the first data pad and outputs the error-corrected data through the first data pad, and
wherein the second memory device includes a second data pad and outputs the error-corrected data via a global multiplexer and through a data pad selected between the first and second data pads according to the channel mode.

3. The memory system of claim 1, wherein the channel mode signal distinguishes between:
a first channel mode in which the first and second memory devices communicate with an external device through the first data pad which is shared by the first and second memory devices, and
a second channel mode in which the first memory device communicates with the external device through the first data pad, and the second memory device communicates with the external device through the second data pad.

4. The memory system of claim 3,
wherein, in the first channel mode, the first memory device delays the read signal by a first channel delay, and the second memory device delays the read signal by a second channel delay, and
wherein, in the second channel mode, both the first and second memory devices delay the read signal by the second channel delay.

5. The memory system of claim 4,
wherein the first channel delay is set to be greater than the second channel delay in each of the first and second memory devices, and
wherein the second channel delay of the first memory device is set to be greater than the second channel delay of the second memory device.

6. The memory system of claim 3,
wherein the first memory device stores the channel mode signal having one of a first logic level indicating the first channel mode and a second logic level indicating the second channel mode, and
wherein the second memory device stores the channel mode signal fixed at the second logic level.

7. The memory system of claim 1, wherein the data latch circuit includes:
a first delay adjustment circuit configured to delay the read signal by one of a first channel delay and a second channel delay according to the channel mode signal to generate the first delayed read signal;
a timing control circuit configured to generate input control signals according to the read signal, and generate output control signals according to the first delayed read signal; and
a timing compensation circuit configured to latch the read data according to the input control signals, and output the latched read data as the delayed data according to the output control signals.

8. The memory system of claim 1,
wherein the data latch circuit is further configured to:
delay a write signal by one of a third channel delay and a fourth channel delay according to the channel mode signal to generate a first delayed write signal;
latch write data according to the write signal; and
output the latched write data as delayed data according to the first delayed write signal, and
wherein the ECC engine is configured to:
generate a preliminary error correction code based on the write data; and
provide the delayed data and the preliminary error correction code to the memory cell region.

9. A memory device comprising:
a memory cell region configured to output read data and a read error correction code according to a read signal;
a delay adjustment circuit configured to delay the read signal by one of a first channel delay and a second channel delay according to a channel mode signal to generate a first delayed read signal;
a timing compensation circuit configured to latch the read data according to the read signal, and output the latched read data as delayed data according to the first delayed read signal; and
an ECC engine configured to correct an error in the delayed data based on the read error correction code to generate error-corrected data.

10. The memory device of claim 9, wherein the delay adjustment circuit includes:
a variable delay configured to delay the read signal by one of the first and second channel delays according to the channel mode signal to generate the first delayed read signal;
a first fixed delay configured to delay the first delayed read signal by a first delay time to generate a second delayed read signal; and
a second fixed delay configured to delay the second delayed read signal by a second delay time to generate a third delayed read signal.

11. The memory device of claim 10, wherein the variable delay includes:
a first delay configured to delay the read signal by the first channel delay;
a second delay configured to delay the read signal by the second channel delay; and
a selector configured to select one of outputs of the first delay and the second delay according to the channel mode signal to output the first delayed read signal.

12. The memory device of claim 10, wherein the ECC engine includes:
a parity generation circuit configured to generate a preliminary error correction code based on the read data;
a syndrome generation circuit configured to generate a syndrome based on the preliminary error correction code and the read error correction code; and
an error correction circuit configured to correct the error in the delayed data based on the syndrome, in synchronization with the second delayed read signal to output the error-corrected data.

13. The memory device of claim 12, further comprising:
a status detection circuit configured to generate at least one of a decoding status flag or a poison flag based on at least one of the read data or the syndrome in synchronization with the second delayed read signal; and
a read driver configured to output the error-corrected data through a data pad in synchronization with the third delayed read signal.

14. The memory device of claim 9, wherein the channel mode signal distinguishes between:
a first channel mode in which the memory device communicates with an external device through a first data pad shared by another memory device, and
a second channel mode in which the memory device communicates with the external device through the first data pad, and the another memory device communicates with the external device through a second data pad included in the another memory device.

15. The memory device of claim 14,
wherein the first channel delay is set to replicate a data transfer delay during a read operation in the first channel mode, and the second channel delay is set to replicate a data transfer delay during a read operation in the second channel mode, and
wherein the first channel delay is greater than the second channel delay.

16. A memory device comprising:
a delay adjustment circuit configured to delay a write signal by one of a first channel delay and a second channel delay according to a channel mode signal to generate a first delayed write signal;
a timing compensation circuit configured to latch write data based on the write signal, and output the latched write data as delayed data according to the first delayed write signal; and
an ECC engine configured to generate a preliminary error correction code based on the write data.

17. The memory device of claim 16, wherein the delay adjustment circuit includes:
a first delay configured to delay the write signal by the first channel delay;
a second delay configured to delay the write signal by the second channel delay;
a selector configured to select one of outputs of the first delay and the second delay according to the channel mode signal to output the first delayed write signal; and
a fixed delay configured to delaying the first delayed write signal by a third delay time to generate a second delayed write signal.

18. The memory device of claim 17, further comprising:
a write driver configured to provide the delayed data and the preliminary error correction code to a memory cell region in synchronization with the second delayed write signal.

19. The memory device of claim 16, wherein the channel mode signal distinguishes between:
a first channel mode in which the memory device communicates with an external device through a first data pad shared by another memory device, and
a second channel mode in which the memory device communicates with the external device through the first data pad, and the another memory device communicates with the external device through a second data pad included in the another memory device.

20. The memory device of claim 19,
wherein the first channel delay is set to replicate a data transfer delay during a write operation in the first channel mode, the second channel delay is set to replicate a data transfer delay during a write operation in the second channel mode, and
wherein the third channel delay is greater than the fourth channel delay.
